(19) United States
(12) Patent Application Publication
(10) Pub. No.: US 2004/0218644 A1
(43) Pub. Date: Nov. 4, 2004

(54) High-power semiconductor laser

(76) Inventors: Ching-Fuh Lin, Taipei (TW); Chia-Wei Tsai, Taipei (TW); Chih-Hung Tsai, Taipei (TW); Yi-Shin Su, Taipei (TW)

Correspondence Address: Jason Z. Lin, Supreme Patent Services, Post Office Box 2339, Saratoga, CA, 95070-0339, US

(21) Appl. No.: 10/622,347

(22) Filed: Jul. 19, 2003

(30) Foreign Application Priority Data
Apr. 30, 2003 (TW) 092110140

(51) Int. Cl. H01S 5/00

(52) U.S. Cl. 372/43; 372/50

(57) ABSTRACT

A high-power semiconductor laser is mainly a light-emitting semiconductor comprising a waveguide structure. The waveguide structure is provided with a plurality of waveguides capable of transmitting light wave, in which a reflective surface for reflecting light wave is formed on a boundary defined by the waveguide and the light-emitting semiconductor unit. A cleaved facet of the light-emitting semiconductor unit has a plurality of interfaces, which are formed by extending the waveguide to reach the cleaved facet of the light-emitting semiconductor unit. The interfaces are provided for either reflecting or transmitting light wave, in which at least a interface would serve for a light-transmitting mechanism. The output power of the present invention could be heightened up to 2 W with an even intensity distribution for a close field without bringing about any catastrophic optical damage (COD).

### BACKGROUND OF THE INVENTION

1. Field of the Invention

The present invention relates generally to a high-power semiconductor laser, and particularly to a semiconductor laser having a specific structure of wave guide capable of heightening the output power thereof to reach that of the diffraction limit.

2. The Prior Arts

Thanks to the matured technology of quantum well, the quantum-well semiconductor laser has been widely applied in various fields, particularly in the field of optical communication and storage. The semiconductor laser is advantageous in: high efficiency for electro-light conversion; applicable directly for electric-exciting; low cost; multiple options for materials; possible for simultaneously distributing in integrated circuits (ICs); minimized volume; and long lifetime.

However, since the saturated light intensity of a generic conventional semiconductor material is somewhat unsatisfactory to result in a relatively low output power (100 mW maximum), an expensive bulky semiconductor laser is usually applied for pump solid-state laser, pump light source for optical fiber amplifier or Raman amplifier, surgical operation, and material processing.

### SUMMARY OF THE INVENTION

As mentioned above, the output power of a conventional semiconductor laser is usually relatively low in the case of a smaller output area because of low intensity of its saturated light, while, on the contrary, if the output area of the laser is expanded by broadening the waveguide thereof, a multi-mode light source could be resulted and the light intensity distribution is probably deteriorated to bring about the so-called catastrophic optical damage (COD). Hence, the present invention is proposed for the purpose of eliminating above defects.

In order to achieve the purpose, the present invention provides a high-power semiconductor laser fabricated by a usual process, in which the inclined angle defined by the waveguide and interface is changed; the path of the waveguide is extended farther so that light wave propagates in the waveguide can be reflected in more times on reflective surfaces defined on the boundary between the waveguide and the light-emitting semiconductor unit to thereby secure a more objective statistical average of the laser light wave. Therefore, it is possible to obtain a better light-intensity distribution and an output power on a par with the diffraction limit when using the high-power semiconductor laser of the present invention.

The merits of the present invention may be summarized in the following:

(1) The output power could be raised up to 2 W or more.

(2) The slope of close distribution is rather slow, unlike the filamentation phenomenon shown in the paste and hence, light will not be concentrated locally and peak intensity can be lowered to alleviate COD under high power conditions.

(3) In the high-power semiconductor laser of the present invention, the wave guide in wave guide structure is broadened to 10 μm up, such that an objective statistical intensity average and even output light distribution can be obtained.

For more detailed information regarding advantages or features of the present invention, at least an example of preferred embodiment will be described below with reference to the annexed drawings.

### BRIEF DESCRIPTION OF THE DRAWINGS

The related drawings in connection with the detailed description of the invention to be made later are described briefly as follows, in which:

FIG. 1 shows a schematic cutaway section of a first embodiment of a high-power semiconductor laser of the present invention;

FIG. 2 shows a schematic cutaway section of a second embodiment of the high-power semiconductor laser of the present invention;

FIG. 3 shows a schematic cutaway section of a third embodiment of the high-power semiconductor laser of the present invention;

FIG. 4 shows a schematic cutaway section of a fourth embodiment of the high-power semiconductor laser of the present invention;

FIG. 5 shows a schematic cutaway section of a fifth embodiment of the high-power semiconductor laser of the present invention;

FIG. 6 shows a schematic cutaway section of a sixth embodiment of the high-power semiconductor laser of the present invention;

FIG. 7 shows a schematic cutaway section of a seventh embodiment of the high-power semiconductor laser of the present invention;

FIG. 8 shows a schematic cutaway section of an eighth embodiment of the high-power semiconductor laser of the present invention;

FIG. 9 shows a schematic cutaway section of the high-power semiconductor laser of the present invention equipped with a ridge-structured waveguide;

FIG. 10 shows a schematic cutaway section of the high-power semiconductor laser of the present invention equipped with an external cavity;

FIG. 11 shows a curve illustrating the relationship between light power and current of the high-power semiconductor laser of the present invention without feedback light;

FIG. 12 shows the far-field distribution of the high-power semiconductor laser of the present invention before resonance;

FIG. 13 shows the optical spectrum of the high-power semiconductor laser of the present invention before resonance;

FIG. 14 shows the far-field distribution of the high-power semiconductor laser of the present invention after resonance;

FIG. 15 shows the optical spectrum of the high-power semiconductor laser of the present invention after resonance;

FIG. 16 shows a plotted curve illustrating the relationship between light and current of the high-power semiconductor laser of the present invention after resonance under feedback light provided by a mirror thereof;

FIG. 17A shows a lighted far-field full-range scanning chart of the high-power semiconductor laser of the present invention under feedback light after resonance;

FIG. 17B shows a lighted far-field scanning chart performed near a main projecting angle of the high-power semiconductor laser of the present invention under feedback light after resonance; and

FIG. 18 shows the near-field distribution with respect to the far-field distribution shown in FIGS. 17A and 17B.

### DETAILED DESCRIPTION OF THE PREFERRED EMBODIMENTS

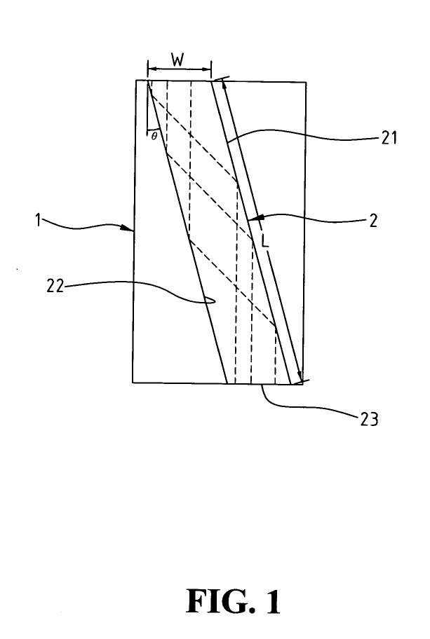

FIG. 1 shows a schematic cutaway section of a first embodiment of a high-power semiconductor laser of the present invention. As shown in FIG. 1, a waveguide structure (2) is formed in a light-emitting semiconductor unit (1). A waveguide (21) for transmitting light wave is formed in the waveguide structure (2), and a reflective surface (22) is prepared in the boundary between the waveguide (21) and the light-emitting semiconductor unit (1), in which every end of the waveguide (21) is extended to intersect a terminal of the light-emitting semiconductor unit (1) to form respective interfaces (23). In FIG. 1, there are two interfaces (23) formed at where the waveguide (21) intersects the light-emitting semiconductor unit (1). These two interfaces have the functions of reflecting light wave and/or transmitting light wave.

The waveguide structure (2) is extended inwardly from an external side of the light-emitting semiconductor unit (1) such that an inclined angle θ contained by the waveguide structure (2) and the normal of the interface (23) could be formed, in which the length L and width W of the waveguide structure (2) should satisfy the condition L≧2 W/tan θ. The light wave emitted from the light-emitting semiconductor unit (1) is reflected by the interface (23) to enter the waveguide structure (2) again, and deflected (see dotted lines) at the reflective surface (22) repeatedly to thereby result in a preferred field distribution according to an average statistical effect, obtainable from the outputted light wave of a certain interface (23).

The foregoing inclined angle θ may be as large to approach as 90° though, 3-50° is preferable when the practical space arrangement is put into consideration.

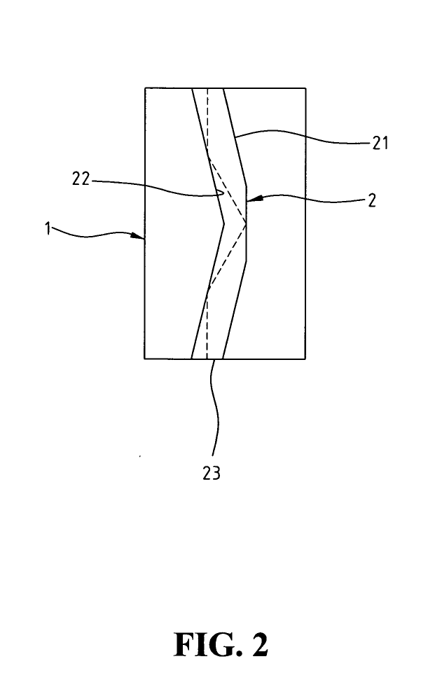

FIG. 2 shows a schematic cutaway section of a second embodiment of the high-power semiconductor laser of the present invention. As shown in FIG. 2, an interface (23) of the waveguide (21) in the waveguide structure (2) is formed at each terminals of the light-emitting semiconductor unit (1), in which an optimum deflection angle is defined in the waveguide (21), and an inclined angle between the waveguide (21) and the normal of a interface (23) is formed under the same condition as of the first embodiment. At this time, the total length of the waveguide structure (2) is longer than that in the first embodiment so that light waves are reflected in multiple times at the reflective surface (22) (represented by dotted path) to obtain a better field distribution of output light waves.

For extending the total length of the waveguide structure (2) in order to secure an optimum field distribution of light wave by statistically averaging multiple reflections, a plurality of reflection points of the waveguide structure (2) may be arranged on the sliced terminals of the light-emitting semiconductor unit (1) to increase some more interfaces (23) for outputting light waves.

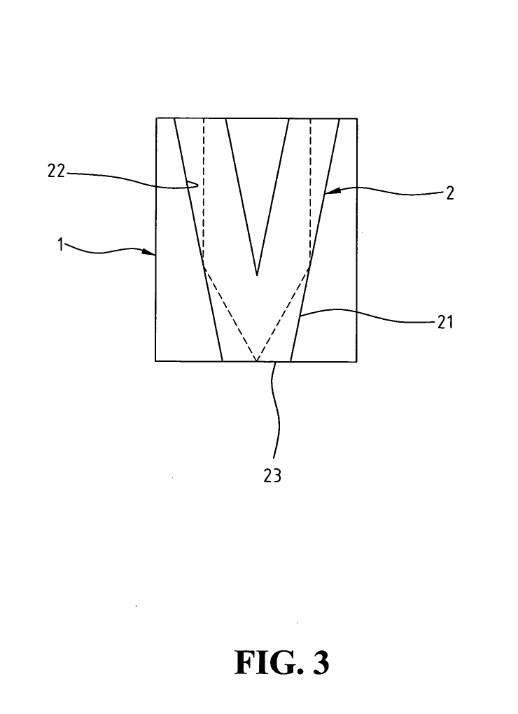

With reference to a preferred third embodiment of the present invention shown in FIG. 3, a V-type deflection angle is formed in the waveguide structure (2) of the light-emitting semiconductor unit (1), in which a interface (23) is formed on a cleaved facet of the light-emitting semiconductor unit (1) at the V deflection point. Here, since the refractive index of the waveguide structure (2) is greater than that of the surrounding light-emitting semiconductor unit (1), the phenomenon of total (or approaching total) internal reflection of incident light waves is liable to happen at the deflection point on the bottom of the waveguide structure (2). Moreover, in the same figure, two interfaces (23) of the waveguide structure (2) in V-formation for outputting light waves could be formed on the same cleaved facet of the light-emitting semiconductor unit (1).

As the inclined angle between the waveguide structure (2) and the normal of an interface (23) for output is limited under 90°, hence, the inclined angle between the waveguide structure (2) and the normal of a interface (23) for reflection should not exceed 45°, preferably in the range of 3-40° when practical space arrangement is put into consideration.

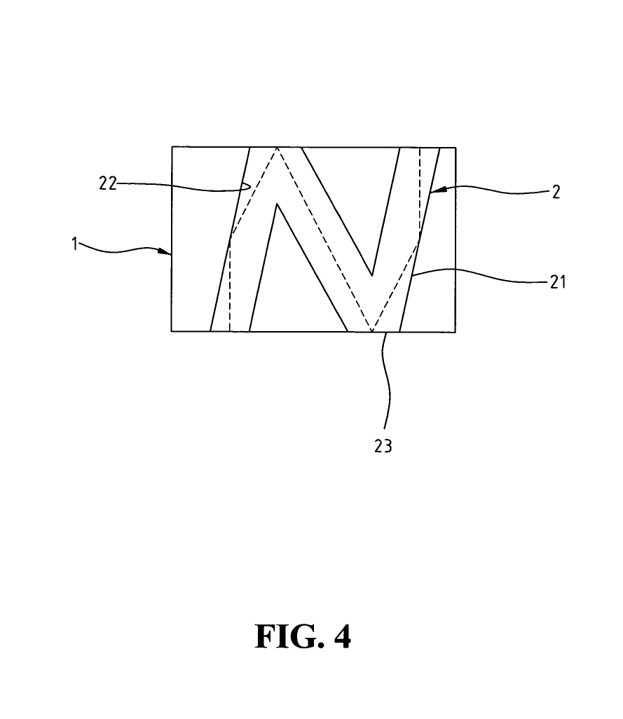

Referring to a fourth embodiment of the present invention shown in FIG. 4, an N-type deflection formation of the waveguide structure (2) includes two interfaces (23) formed at an upper and a lower cleaved facet of the light-emitting semiconductor unit (1) respectively. Since the refractive index of the waveguide structure (2) is greater than that of the light-emitting semiconductor unit (1), the phenomenon of total (or approaching total) internal reflection of incident light waves is liable to happen at the deflection points of the N-type deflection formation should the deflection angle be large enough. Furthermore, two interfaces (23) of the waveguide structure (2) for outputting light waves could be formed on respective different cleaved facets of the light-emitting semiconductor (1).

Two lateral segments of the waveguide structure (2) in the light-emitting semiconductor unit (1) shown in FIG. 4 are parallel with each other, and the inclined angle defined by the middle segment of the waveguide structure (2) and the normal of the interface (23) is the double of that defined by each lateral segment of the waveguide structure (2) and the normal of the interface (23).

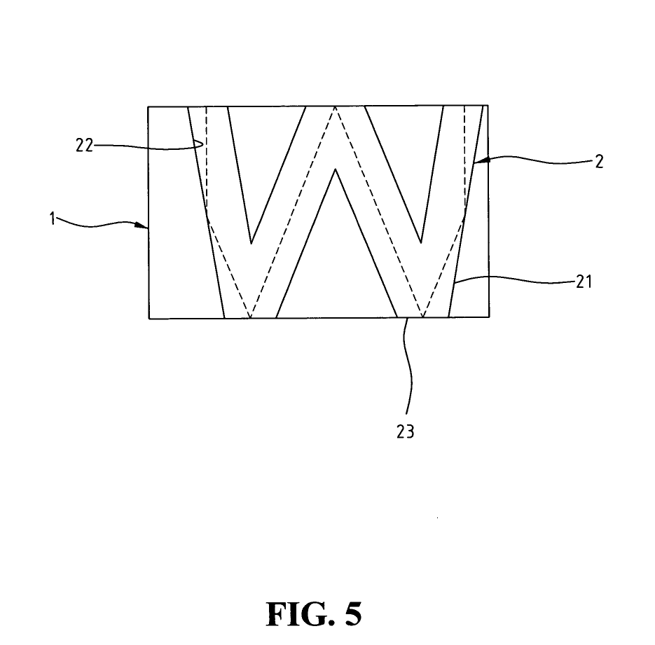

FIG. 5 shows a schematic cutaway section of a fifth embodiment of the high-power semiconductor laser of the present invention. As shown in FIG. 5, the waveguide structure (2) in the light-emitting semiconductor unit (1) is a W-type deflection formation, in which a interface (23) is formed at the intersection between each of three deflection points of the deflection formation and each cleaved facet of the light-emitting semiconductor unit (1). Now, Since the refractive index of the waveguide structure (2) is greater than that of the light-emitting semiconductor unit (1), the phenomenon of total (or approaching total) internal reflection of incident light waves is liable to happen at the deflection points of the W-type deflection formation should the deflection angle be large enough. Furthermore, two interfaces (23) of the waveguide structure (2) in W-formation for outputting light waves could be formed on the same cleaved facet of the light-emitting semiconductor (1).

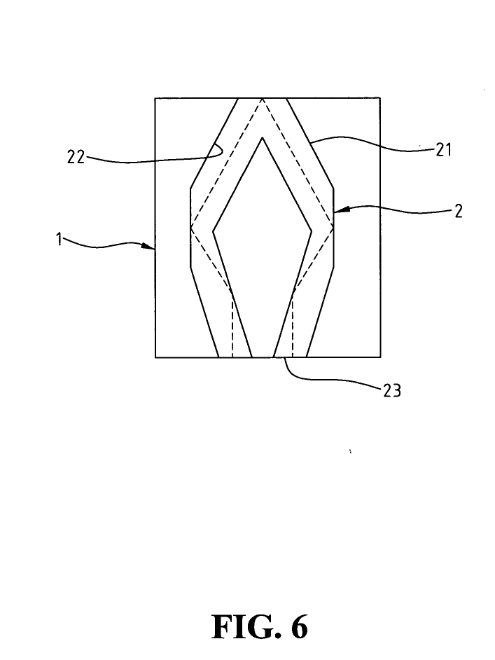

FIG. 6 shows a schematic cutaway section of a sixth embodiment of the high-power semiconductor laser of the present invention. As shown in FIG. 6, a deflection formation having three deflection points is provided to the waveguide structure (2) of the light-emitting semiconductor unit (1), in which a interface (23) is formed on a cleaved facet of the light-emitting semiconductor unit (1) at the second deflection point. Since the refractive index of the waveguide structure (2) is greater than that of the light-emitting semiconductor unit (1), therefore, the phenomenon of total (or approaching total) internal reflection of incident light waves is liable to happen at the deflection points should the deflection angle be large enough. Furthermore, two interfaces (23) of the waveguide structure (2) having three deflection points for outputting light waves could be formed on the same cleaved facet of the light-emitting semiconductor (1).

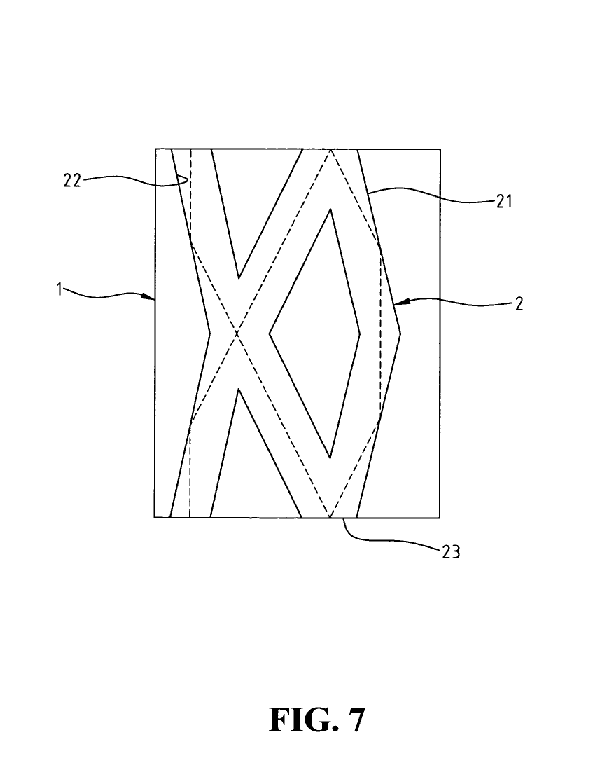

FIG. 7 shows a schematic cutaway section of a seventh embodiment of the high-power semiconductor laser of the present invention. As shown in FIG. 7, the waveguide structure (2) in the light-emitting semiconductor unit (1) is an α-type deflection formation, in which the path thereof is extended from a cleaved facet to the other of the light-emitting semiconductor unit (I) to create a deflection point and a interface (23); then it is extended farther towards the original cleaved facet of the light-emitting semiconductor unit (1) to form another deflection point and subsequently, on the original cleaved facet, yet another deflection point and interface (23); then the path is reflected to go back towards the other cleaved facet to form yet another deflection point en route and another interface (23) at an intersection with the other cleaved facet of the light-emitting semiconductor unit (1). Now, Since the refractive index of the waveguide structure (2) is greater than that of the light-emitting semiconductor unit (1), the phenomenon of total (or approaching total) internal reflection of incident light waves is liable to happen at the deflection points should the α-type deflection angle be large enough. Furthermore, two interfaces (23) of the waveguide structure (2) in a-formation for outputting light waves could be formed on different cleaved facets of the light-emitting semiconductor (1).

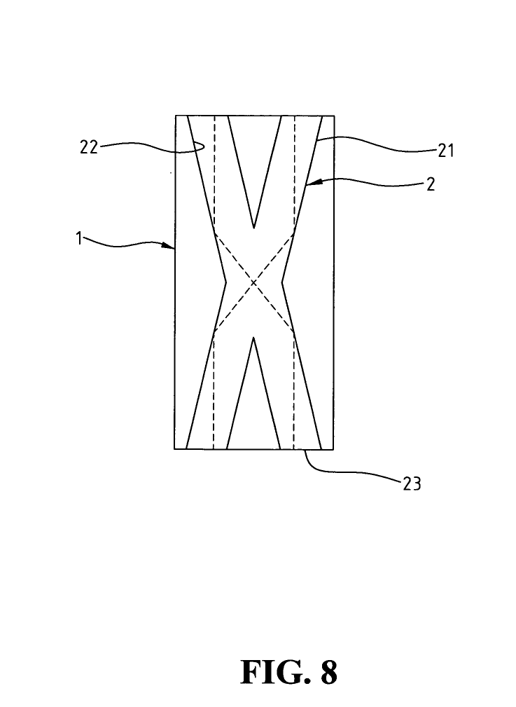

An eighth embodiment shown in FIG. 8 is another example for increasing amount of the interface (23) on cleaved facet of the waveguide structure (2) for outputting light waves. In FIG. 8, the waveguide structure (2) in the light-emitting semiconductor unit (1) is an X-type deflection formation, in which each of three deflection points forms a interface (23) on respective cleaved facets of the light-emitting semiconductor unit (1). Since the refractive index of the waveguide structure (2) is greater than that of the light-emitting semiconductor unit (1), the phenomenon of total (or approaching total) internal reflection of incident light waves is liable to happen at the deflection points should the deflection angle of the X-type deflection formation be large enough. Furthermore, two interfaces (23) of the waveguide structure (2) in X-formation for outputting light waves could be formed on the same cleaved facet of the light-emitting semiconductor (1).

In foregoing structure of semiconductor laser, there are options for the width of a practical waveguide structure (2) for deciding a far-field distribution angle. Also, there are options for the length and oblique angle of the waveguide structure (2). However, the selection is dependent on a selected width so as to achieve the multi-reflection purpose and oscillation of light wave on and among the reflective surfaces (22).

Moreover, as illustrated in FIG. 9, in order to secure a better reflection effect of the reflective surface (22), the waveguide (21) of the waveguide structure (2) is constructed in a ridge or buried-hetero structure.

In the ridge-structured waveguide (21), two sides of the ridge are etched to a lower level than the ridge structure itself, and the etched depth is limited to 200 nm above or below an active layer (25).

The refractive index of the waveguide structure is larger than that of the light-emitting semiconductor unit (1).

A broad width, particularly 10 μm up, is adopted for the waveguide (21) of the waveguide structure (2).

In foregoing structure of semiconductor laser, an interface (23) may be formed on a broken interface of crystal boundaries of the semiconductor or by dry etching.

Besides, the interface (23) may be coated for high reflectivity.

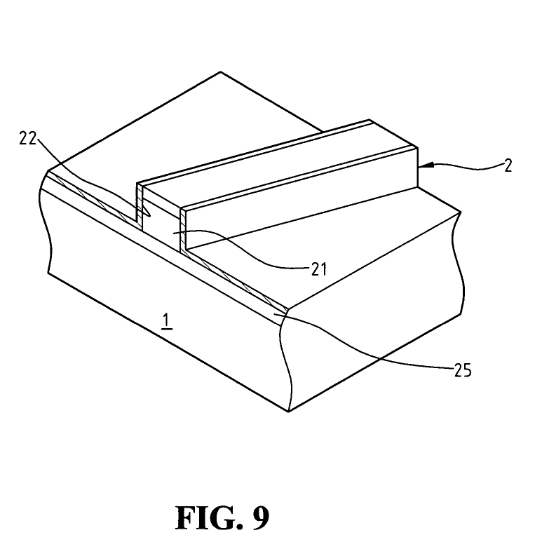

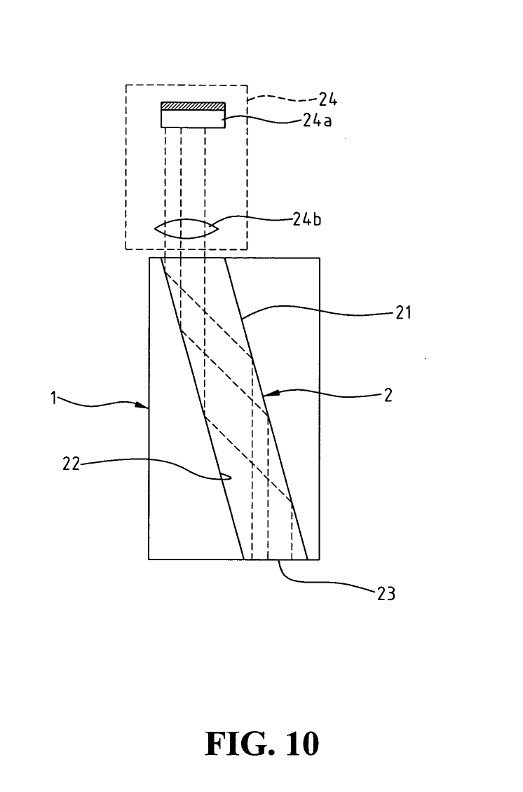

As illustrated in FIG. 10, in foregoing structure of semiconductor laser, there is at least a interface (23) connecting to an external-cavity configuration (24) composed of a mirror surface (24a) and a lens (24b) such that a light beam is allowed to penetrate through the interface (23), then project on the lens (24b) of the external-cavity configuration (24) to reach the mirror surface (24a) and reflect back into the waveguide structure (2) of the light-emitting semiconductor unit (1) along the original path.

Here, the high-power semiconductor laser of the present invention is to be proven that its output power can reach that of the diffraction limit through a first embodiment of a high-power semiconductor laser manufactured by way of a generic semiconductor fabricating process, in which the inclined angle contained by the waveguide structure (2) and a interface (23) is about 7°, and the waveguide of the waveguide structure is ridge-structured. The conclusions of the present invention may be summarized as the following:

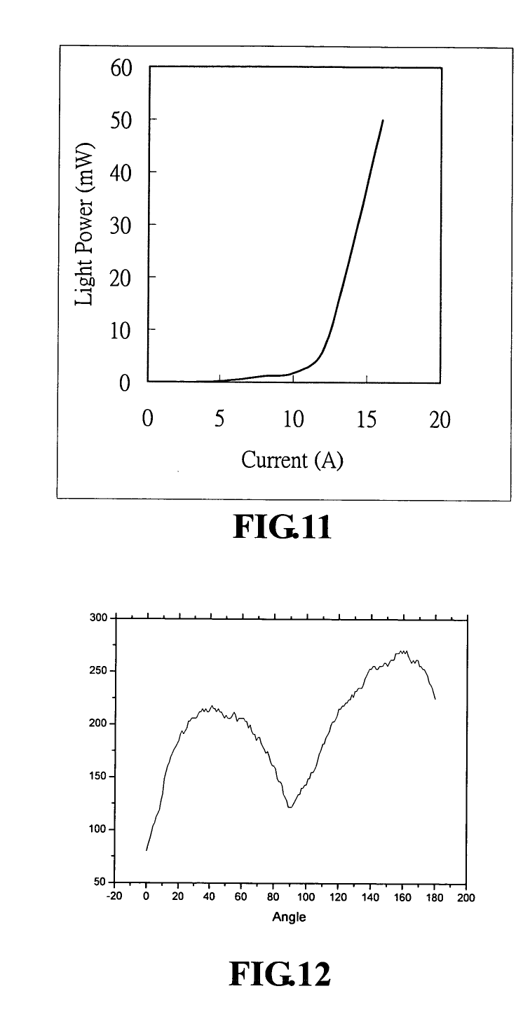

(1) The relationship between light power and current of the high-power semiconductor laser of the present invention shown in FIG. 11 is about the same compared with that of a generic semiconductor laser.

(2) The far field of light before resonance of the high-power semiconductor laser of the present invention is shown in FIG. 12.

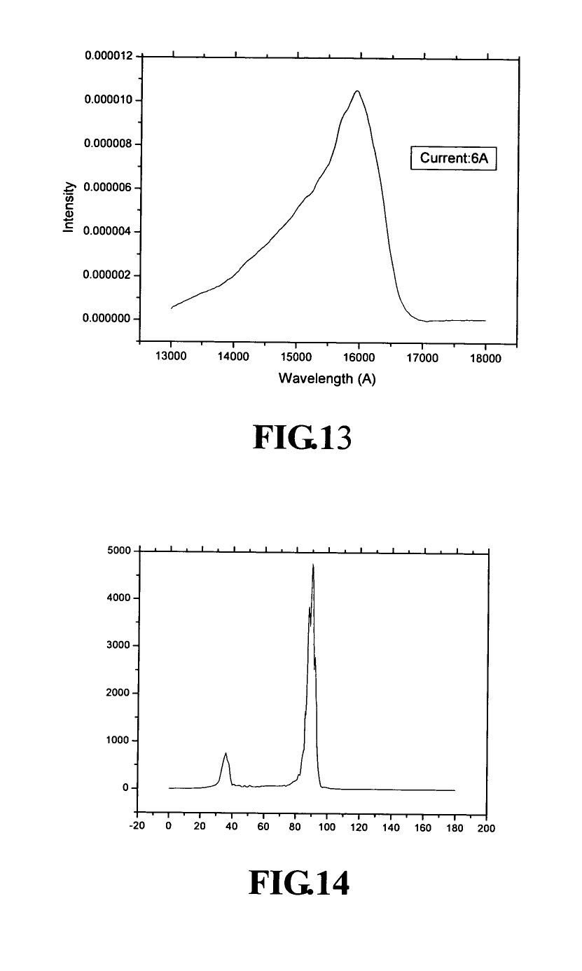

(3) The spectral distribution is rather wide before resonance of the high-power semiconductor laser of the present invention as shown in FIG. 13.

(4) As shown in FIG. 14, after resonance, the gain of the semiconductor laser of the present invention is boosted to drive light to propagate along the dotted lines shown in FIG. 1 and resonated between two mirror surfaces, where the far-field distribution angle is about 5°.

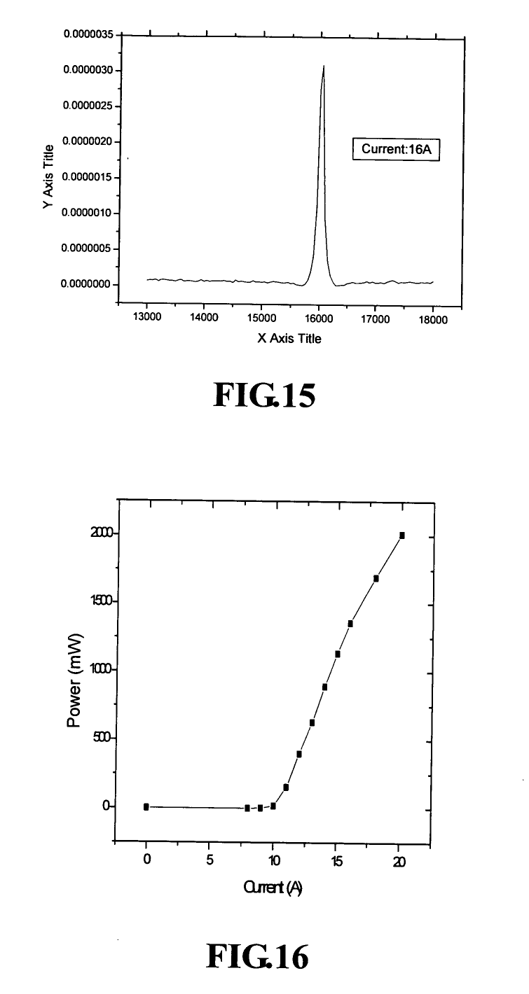

(5) After resonance, the spectral distribution of the semiconductor laser of the present invention is relatively narrow as shown in FIG. 15.

(6) As shown in FIG. 16, after resonance of the semiconductor laser of the present invention and when a light beam of a interface (23) is fed back into the waveguide structure (2) by an external-cavity configuration for example, the light intensity from another interface will be boosted as high as 2 W in this case.

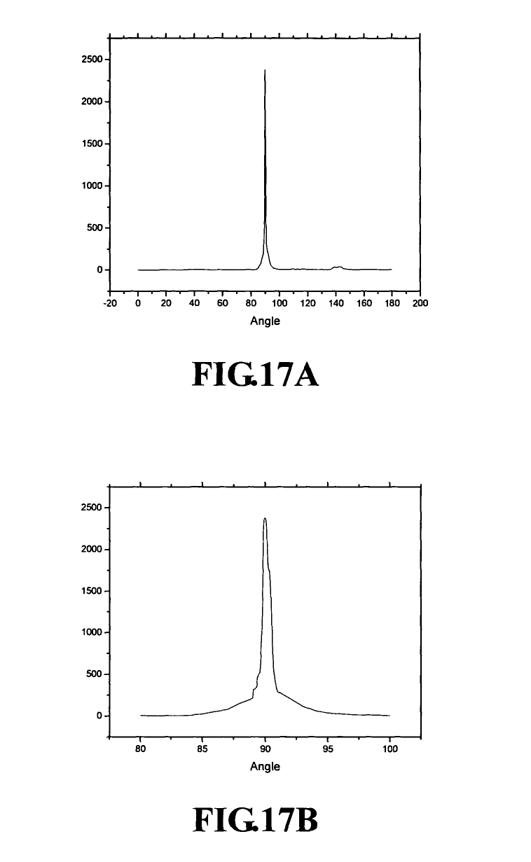

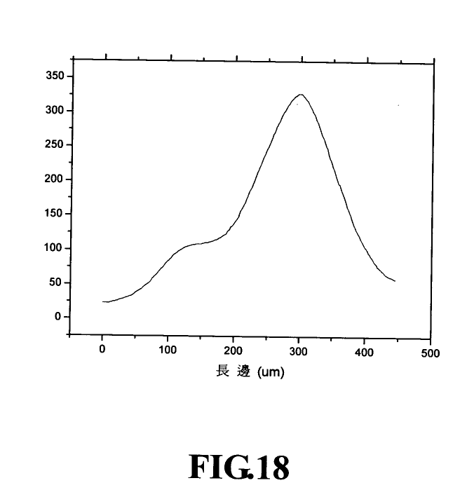

(7) As shown in FIG. 17, after resonance, the far-field distribution angle is narrowed to 0.7° approximately when a light beam of a interface (23) is fed back into the waveguide structure (2). The near field shown in FIG. 18 corresponding to the far field reveals a diffraction limit according to optical principles. The feedback light is supposed to enhance the resonance along the dotted lines shown in FIG. 1 to thereby boost the power to achieve the diffraction limit. Also, the reflectivity of the interface (23) may be heightened by coating a plated film thereon.

In the above described, the preferred embodiments have been described in detail with reference to the drawings annexed, and it is apparent that numerous changes or modifications may be made without departing from the true spirit and scope thereof, as set forth in the claims below.

What is claimed is:

1. A high-power semiconductor laser, in which a waveguide structure is formed in a light-emitting semiconductor unit; a plurality of waveguides for propagating light wave is provided to the waveguide structure, and the boundary of each waveguide serves as a reflective surface for reflecting light wave; a plurality of interfaces for reflecting or transmitting light wave is formed by extending the waveguide to intersect with the cleaved facets of the light-emitting semiconductor unit, in which at least an interface is used for transmitting light; the width of the waveguide is more than 10 μm; and the direction of each waveguide is not perpendicular at least to the direction of a partial section of a interface connected with that waveguide.

2. The semiconductor laser according to claim 1, wherein the waveguide structure is provided with a waveguide capable of propagating light wave, and both ends of the waveguide are extended to reach the cleaved facet of the light-emitting semiconductor unit and form two interfaces there.

3. The semiconductor laser according to claim 2, wherein an inclined angle defined by the waveguide of the waveguide structure and the normal of a connected corresponding interface is 3-50 degrees.

4. The semiconductor laser according to claim 2, wherein the waveguide of the waveguide structure has an optimum deflection angle.

5. The semiconductor laser according to claim 1, wherein the waveguide structure has at least two waveguides capable of propagating light wave, and the cleaved facet of the light-emitting semiconductor unit forms two interfaces, in which each interface is connected with a corresponding waveguide so that light wave is propagating through every waveguide sequentially.

6. The semiconductor laser according to claim 5, wherein the waveguide structure has two waveguides capable of propagating light wave, and the inclined angle defined by each waveguide of the waveguide structure and the normal of the interface is 3-40 degrees.

7. The semiconductor laser according to claim 5, wherein at least a waveguide of the waveguide structure has a proper deflection angle.

8. The semiconductor laser according to claim 1, wherein the waveguide structure has at least two waveguides capable of propagating light wave, and four interfaces are formed by the cleaved facets of the light-emitting semiconductor unit, in which each interface is connected with a corresponding waveguide such that light wave is transmittable through every waveguide.

9. The semiconductor laser according to claim 8, wherein the waveguide structure has three waveguides capable of propagating light wave, and each interface is connected with a corresponding waveguide for transmitting light wave through every waveguide in order.

10. The semiconductor laser according to claim 8, wherein the waveguide structure has four waveguides capable of propagating light wave, and each interface is connected with a corresponding waveguide for transmitting light wave through every waveguide in order.

11. The semiconductor laser according to claim 8, 9, or 10, wherein at least a waveguide of the waveguide structure has a proper deflection angle.

12. The semiconductor laser according to claim 9, wherein two interfaces are formed on two opposite cleaved faces of the light-emitting semiconductor unit respectively; the total four interfaces are connected with respective corresponding waveguides, in which two of three waveguides form a parallel configuration while the third waveguide is connected with two interfaces of those two waveguides located at different cleaved facets such that light wave can be transmitted through every waveguide; an inclined angle defined by those two waveguides in parallel and the normal of respective interfaces is 3-40 degrees; and the inclined angle defined by the third waveguide and its corresponding interface is the double of that defined by those two waveguides and the normal of their corresponding interfaces.

13. The semiconductor laser according to claim 9, wherein two interfaces are formed respectively on two opposite cleaved facets of the light-emitting semiconductor unit; each of those four interfaces is connected with a corresponding waveguide, in which two of those three waveguides construct a staggered formation, and the third waveguide is provided with a proper deflection angle and connected to two interface on the same lateral different cleaved facets of the two waveguides to enable light wave to transmit through every waveguide.

14. The semiconductor laser according to claim 1, wherein the waveguide structure has at least three waveguides capable of propagating light wave, and the cleaved facet of the light-emitting semiconductor unit forms five interfaces, in which each interface is connected with a corresponding waveguide such that light wave can be transmitted through every waveguide.

15. The semiconductor laser according to claim 14, wherein the waveguide structure has four waveguides capable of transmitting light wave, and each interface is connected with a corresponding waveguide to enable light wave to propagate through every waveguide.

16. The semiconductor laser according to claim 14, wherein the waveguide structure has at least five waveguides capable of transmitting light wave, and the cleaved facet of the light-emitting semiconductor unit forms five interfaces, in which each interface is connected with a corresponding waveguide such that light wave can be transmitted through every waveguide.

17. The semiconductor laser according to claim 14, 15 or 16, wherein at least a waveguide has a proper deflection angle.

18. The semiconductor laser according to claim 1, wherein the waveguide is in the form of a V-type or X-type or W-type or N-type or a α-type or any combination of these types.

19. The semiconductor laser according to claim 1, 2, 5, 8 or 14, wherein the waveguide structure is a ridge formation.

20. The semiconductor laser according to claim 18, wherein the ridge formation is made by dry etching or chemical etching.

21. The semiconductor laser according to claim 18, wherein two laterals of the ridge formation are lower than the ridge formation itself.

22. The semiconductor laser according to claim 18, wherein the laterals of the ridge are etched down with the etched depth from 50 nm to 200 nm higher or lower than an active layer.

23. The semiconductor laser according to claim 1, 2, 5, 8 or 14, wherein the waveguide structure is a buried-hetero structure.

24. The semiconductor laser according to claim 1, 2, 5, 8 or 14, wherein the equivalent refractive index inside the waveguide structure is larger than outside the waveguide structure.

25. The semiconductor laser according to claim 1, 2, 5, 8 or 14, wherein light wave is supposed to reflect on an inside reflective surface of the waveguide structure at two positions at least.

26. The semiconductor laser according to claim 1, 2, 5, 8 or 14, wherein the width of the waveguide in the waveguide structure is greater than 10 μm.

27. The semiconductor laser according to claim 1, 2, 5, 8 or 14, wherein, except for outputting light wave, there is at least an interface coated with a thin film or multiple thin films to have high reflection.

28. The semiconductor laser according to claim 1, 2, 5, 8 or 14, wherein incident light wave would enter an external-cavity configuration through at least an interface, then the light wave is reflected back to the light-emitting semiconductor unit.

29. The semiconductor laser according to claim 28, wherein the external-cavity configuration has a mirror as the feedback reflector.

30. The semiconductor laser according to claim 28, wherein the external-cavity configuration has a grating as the feedback reflector.

31. The semiconductor laser according to claim 1, 2, 5, 8 or 14, wherein the width of the waveguide in the waveguide structure is designed relatively wider.

32. The semiconductor laser according to claim 1, 2, 5, 8 or 14, wherein the interface may be formed on a broken interface of crystal boundaries of the semiconductor or by dry etching.
